(19) United States
(12) Patent Application Publication
(10) Pub. No.: US 2025/0351508 A1
(43) Pub. Date: Nov. 13, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuei-Yu KAO, Hsinchu (TW); Chun-Yu LIN, Hsinchu (TW); Ke-Chia TSENG, Hsinchu (TW); Guan Kai HUANG, Hsinchu (TW); Chun-Hung CHEN, Hsinchu (TW)

(73) Assignee: Taiwan Semiconductor Manufacturing Company, Ltd., Hsinchu (TW)

(21) Appl. No.: 18/661,163

(22) Filed: May 10, 2024

(51) Int. Cl. H01L 29/66; H01L 21/84; H01L 27/12; H01L 29/06; H01L 29/423; H01L 29/49; H01L 29/775; H01L 29/786

(52) U.S. Cl. CPC H10D 64/017; H10D 30/014; H10D 30/43; H10D 30/6735; H10D 30/6757; H10D 62/121; H10D 64/018; H10D 64/661; H10D 86/01; H10D 86/201

(57) ABSTRACT

A method of fabricating a semiconductor device includes forming an isolation insulating layer over a substrate. A sacrificial gate layer is formed over the isolation insulating layer. The sacrificial gate layer is patterned to form sacrificial gate structures. A spacer layer is formed over the sacrificial gate structures. An interlayer dielectric layer is formed over the sacrificial gate structures. The sacrificial gate structures are removed to form openings over the isolation insulating layer. A residual amount of each sacrificial gate structure remains at the bottom of a respective opening over the isolation insulating layer. Metal gate electrodes are formed in the openings. The metal gate electrodes include a first material and the residual amount comprises a second material different from the first material.

### BACKGROUND

As the semiconductor industry has progressed into nanometer technology process nodes in pursuit of higher electrical conductivity, higher device density, higher performance, and lower costs, challenges from both fabrication and design issues have resulted in the development of designs, such as a field effect transistors (FET) including a fin FET (FinFET), nanosheet FET (NSFET), metal-oxide-semiconductor FET (MOSFET), and a gate-all-around (GAA) FET. Conventional etching techniques to replace sacrificial gates with metal gates results in the shape of the metal gate extending near the source/drain region which leads to increased parasitic capacitance and reduces the electrical conductivity of the transistor. The etching of a sacrificial gate structure with prior etching techniques that utilize a combination of dry and wet etching processes causes excessive rounding or punch etching into the isolation insulating layer. The loss of the isolation insulating layer and extension of the metal gate near the source/drain epitaxial region leads to undesirable parasitic capacitance. As transistor dimensions are continually scaled down to sub 20-25 nm technology nodes, further improvements are required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A-1E show various views of a semiconductor device according to embodiments of the present disclosure. FIG. 1A is a partial plan view of the semiconductor device. FIG. 1B is a cross sectional view corresponding to A-A′ of FIG. 1A. FIG. 1C is a cross sectional view corresponding to B-B′ of FIG. 1A.

FIG. 1D shows an isometric view of a semiconductor device according to embodiments of the present disclosure, and FIG. 1E shows a partial isometric view of FIG. 1D according to embodiments of the present disclosure.

FIG. 2 shows a cross sectional view of one of the various stages of manufacturing a semiconductor device according to an embodiment of the present disclosure.

FIG. 3A shows a cross sectional view and FIG. 3B shows an isometric view of one of the various stages of manufacturing a semiconductor device according to embodiments of the present disclosure.

FIGS. 4A and 4B show cross sectional views of one of the various stages of manufacturing a semiconductor device according to embodiments of the present disclosure.

FIGS. 5A and 5B show cross sectional views of one of the various stages of manufacturing a semiconductor device according to embodiments of the present disclosure.

FIGS. 6A and 6B show cross sectional views of one of the various stages of manufacturing a semiconductor device according to embodiments of the present disclosure.

FIGS. 7A and 7B show cross sectional views of one of the various stages of manufacturing a semiconductor device according to embodiments of the present disclosure.

FIGS. 8A and 8B show cross sectional views of one of the various stages of manufacturing a semiconductor device according to embodiments of the present disclosure.

FIG. 8C shows a cross sectional view of one of the various stages of manufacturing a semiconductor device according to embodiments of the present disclosure.

FIGS. 9A and 9B show cross sectional views of one of the various stages of manufacturing a semiconductor device according to embodiments of the present disclosure.

FIGS. 10A and 10B show partial cross sectional views of a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” and the like, may be used herein for ease of description to describe one element or a feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one or both of the source and the drain. In the following embodiments, materials, configurations, dimensions, processes, and/or operations as described with respect to one embodiment (e.g., one or more figures) may be employed in the other embodiments, and a detailed description thereof may be omitted. Source/drain structure(s) may refer to a source or a drain, individually or collectively dependent upon the context.

Disclosed embodiments relate to a semiconductor device, in particular, a FET gate structure such as, but not limited to, a GAA FET. Other disclosed embodiments include a method of fabricating a semiconductor device, in particular, a method of fabricating a FET gate structure such as, but not limited to, a GAA FET.

In embodiments of the disclosure, the electrical conductivity and performance of a semiconductor device are optimized by reducing the parasitic capacitance of the device. Embodiments of the disclosure minimize the extension of the metal gate into the isolation insulating region near the source/drain region and allow the device to operate with increased performance and improved electrical conductivity. In certain embodiments, parasitic capacitance is reduced after metal gate replacement by limiting the extension of the metal gate into the isolation insulating region near the source/drain epitaxial area. In certain embodiments, with the reduced parasitic capacitance, the electric current of the device is increased and device yield is improved.

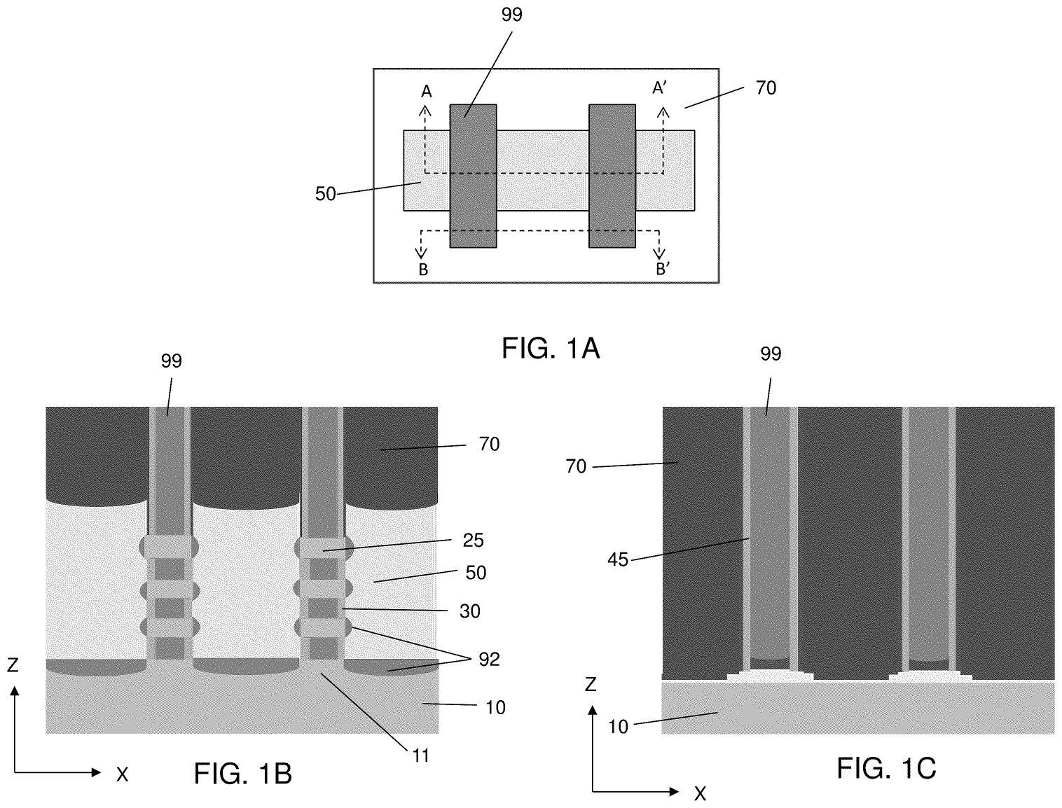

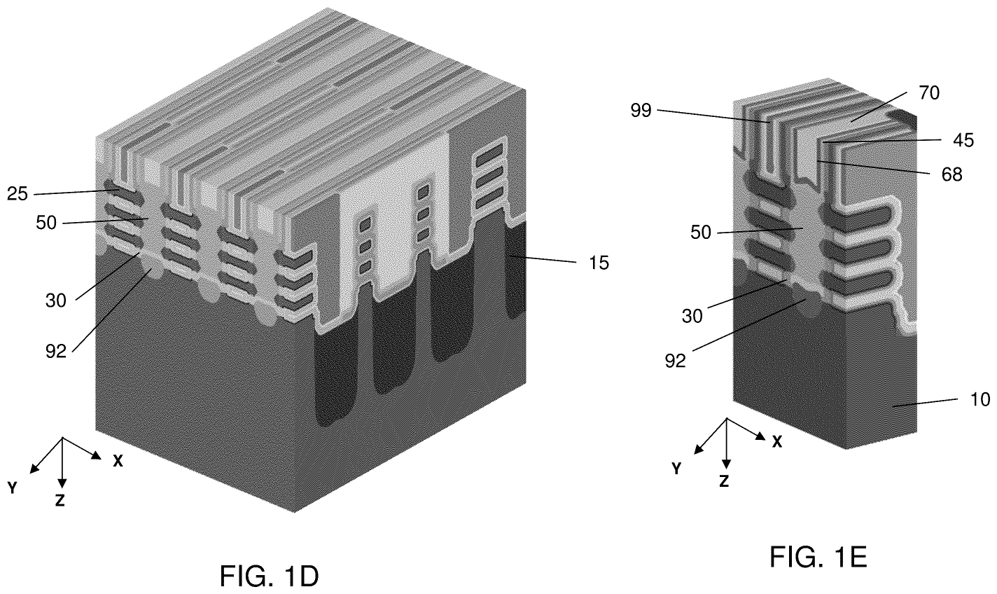

FIGS. 1A-1E are schematic illustrations showing various views of a semiconductor device such as a GAA FET semiconductor device according to an embodiment of the present disclosure. Other embodiments include FET semiconductor devices including fin FET (FinFET), nanosheet FET (NSFET), and metal-oxide-semiconductor FET (MOSFET).

FIG. 1A is a partial plan view of a GAA FET. The GAA FET includes metal gates 99 and epitaxial source-drain structures 50. FIG. 1B is a cross sectional view along the X direction corresponding to line A-A′ of FIG. 1A cut along the channel region of an inner gate of the GAA FET. FIG. 1C is a cross sectional view along the X direction corresponding to line B-B′ of FIG. 1A cut along an outer gate of the GAA FET. In certain embodiments, the inner gate is disposed over the channel region, and the outer gate is disposed over the isolation layer. FIGS. 1D and 1E show isometric views of a GAA FET semiconductor device according to one embodiment of the present disclosure, consistent with what is shown in FIGS. 1A-1C.

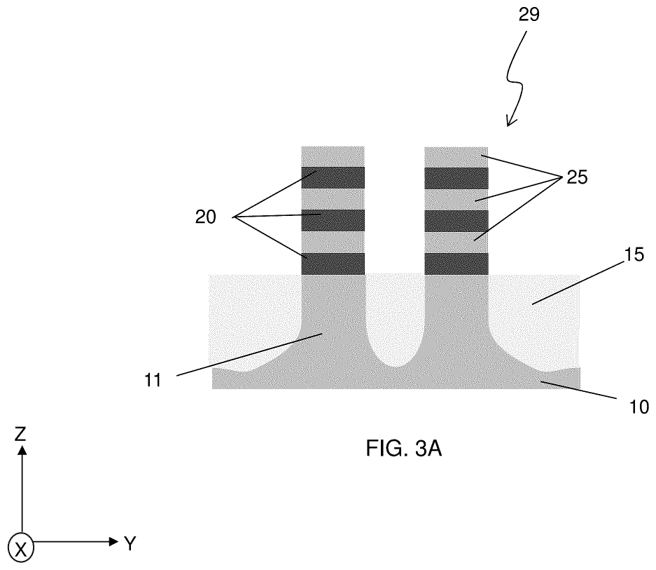

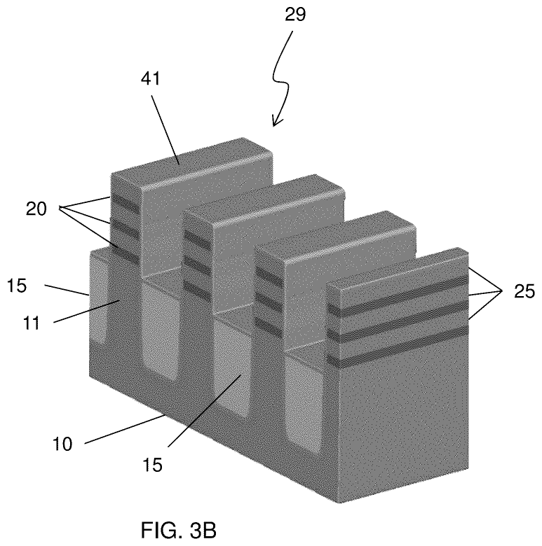

As shown in FIG. 1B, semiconductor nanostructures 25 are provided over a semiconductor substrate 10 and vertically arranged along the Z direction (the normal direction to the principal surface of the substrate 10). As shown in FIG. 1B, the semiconductor nanowires or nanosheets (collectively nanostructures) 25, which are channel layers, are disposed over the substrate 10. In some embodiments, the semiconductor nanostructures 25 are disposed over a fin structure 11 (see, FIG. 3A) protruding from the substrate 10 (a bottom fin structure 11). In certain embodiments, each of the channel layers 25 is wrapped around by a gate dielectric layer, and one or more conductive layers including one or more work function adjustment layers and a gate electrode layer. In some embodiments, the semiconductor nanostructures 25 are made of Si, SiGe, or Ge.

In some embodiments, an interfacial dielectric layer (not shown) is formed between the channel of the semiconductor nanostructure 25 and the gate dielectric layer. In some embodiments, the gate dielectric layer includes a high-k dielectric layer. The gate structure includes the gate dielectric layer, the gate electrode layer, and gate sidewall spacers. The gate sidewall spacers are insulating sidewall spacers (or insulating spacers or sidewall spacers) in some embodiments. In some embodiments, the gate structure includes a work function adjustment layer disposed between the gate dielectric layer and the gate electrode layer.

Although FIG. 1B shows three semiconductor nanostructures 25, the number of the semiconductor nanostructures 25 is not limited to three, and may be as small as one or more than three, and may be up to ten. By adjusting the number of semiconductor nanostructures (nanowires, nanosheets . . . , etc.), the driving current of the GAA FET device can be adjusted.

In some embodiments, source/drain structures 50 are disposed on opposing sides of the metal gate structures 99. In some embodiments, an epitaxial layer 92 is disposed on the lateral end face of the nanosheets 25 and exposed surfaces of the lower fin structure 11, as shown in FIG. 1B. In certain embodiments, inner spacers 30 separate the metal gate structures 99 and source/drain structures 50. The inner spacers are made of an insulating material and may be made of the same material as the gate sidewall spacers 45 (FIG. 1C).

In certain embodiments, a source/drain (S/D) contact (not shown) contacts the source/drain structures 50. In some embodiments, the S/D contact includes one or more metal or metallic layers of Ti, TiN, Ta, TaN, Co, W, or an alloy thereof. In some embodiments, a silicide layer (not shown) is formed on the source/drain structures 50 before the S/D contact is formed. In some embodiments, the silicide layer includes WSi, NiSi, TiSi, CoSi, or other suitable silicide material or an alloy of a metal element and silicon and/or germanium.

In some embodiments, an interlayer dielectric (ILD) layer 70 is disposed over the S/D structures 50 and a conductive contact layer (e.g., plug or bar) (not shown) passing through the ILD layer 70 is disposed on the S/D structure 50. In other embodiments, the ILD layer 70 includes one or more layers of insulating material, such as silicon oxide, a silicon nitride, SiON, SiOC, SiOCN, or any other suitable insulating materials.

In some embodiments, a refill insulating layer (not shown) is disposed between the uppermost portion of the metal gate electrode 99 and the ILD layer 70. The refill insulating layer includes one or more layers of insulating material, such as silicon oxide, silicon nitride, SiCN, SiON, SiOCN, or any other suitable insulating materials.

In some embodiments, a contact etch stop layer 68 (FIG. 1E) is disposed between the ILD layer 70 and the S/D structures 50. In some embodiments, the contact etch stop layer 68 includes one or more layers of silicon nitride, SiON, SiOC, SiOCN, or any other suitable insulating materials.

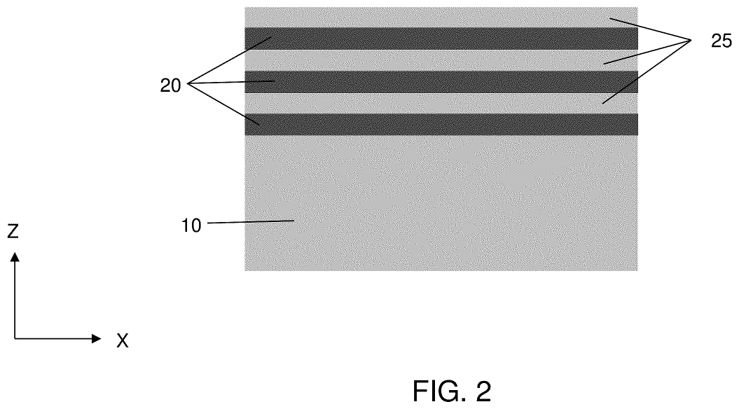

FIGS. 2 to 9B are schematic illustrations showing various stages of manufacturing a semiconductor device according to an embodiment of the present disclosure. It is understood that additional operations can be provided before, during, and after processes shown by FIGS. 2-9B, and some of the operations described below can be replaced or eliminated, for additional embodiments of the method. The order of the operations/processes may be interchangeable. Same and/or similar materials, configurations, dimensions, and/or processes may be employed. Although not shown in FIGS. 2-9B, in some embodiments, the gate region and the source/drain structure are repeatedly arranged in the X direction in the desired numbers depending on the design requirements.

As shown in FIG. 2, first semiconductor layers 20 and second semiconductor layers 25 are alternately formed over the substrate 10. The first semiconductor layers 20 and the second semiconductor layers 25 are made of materials having different lattice constants and may include one or more layers of silicon (Si), germanium (Ge), SiGe, GaAs, InSb, GaP, GaSb, InAlAs, InGaAs, GaSbP, GaAsSb or InP.

In some embodiments, the first semiconductor layers 20 and the second semiconductor layers 25 are made of Si, a Si compound, SiGe, Ge, or a Ge compound. In some embodiments, the first semiconductor layers 20 are made of Si. In some embodiments, the first semiconductor layers 20 are made of Si₁₋ₓGeₓ, where x is equal to or more than about 0.1 and equal to or less than about 0.6, and the second semiconductor layers 25 are Si or Si_{1-y}Ge_{y}, where y is smaller than x and equal to or less than about 0.2.

In other embodiments, the second semiconductor layers 25 are made of Si₁₋ₓGeₓ, where x is equal to or more than about 0.1 and equal to or less than about 0.6, and the first semiconductor layers 20 are made of Si or Si_{1-y}Ge_{y}, where y is smaller than x and equal to or less than about 0.2. In some embodiments, the second semiconductor layer 25 is made of the same material as the semiconductor substrate 10.

The first semiconductor layer 20 and the second semiconductor layer 25 may be formed by one or more epitaxy or epitaxial (epi) processes. The epitaxy processes include CVD deposition techniques (e.g., vapor-phase epitaxy (VPE) and/or ultra-high vacuum CVD (UHV-CVD)), molecular beam epitaxy, and/or other suitable processes.

The first semiconductor layers 20 and the second semiconductor layers 25 are epitaxially formed over the substrate 10 alternately. The thickness of the first semiconductor layers 20 may be equal to or greater than that of the second semiconductor layers 25, and is in a range from about 4 nanometers (nm) to about 30 nm in some embodiments, and is in a range from about 5 nm to about 15 nm in other embodiments. The thickness of the second semiconductor layers 25 is in a range from about 4 nm to about 30 nm in some embodiments and is in a range from about 5 nm to about 15 nm in other embodiments. The thickness of the first semiconductor layers 20 may be the same as, or different from the thickness of the second semiconductor layers 25. Although three first semiconductor layers 20 and three second semiconductor layers 25 are shown in FIG. 2, the numbers are not limited to three and can be one, two, or more than 3, and less than twenty. In some embodiments, the number of the first semiconductor layers 20 is greater by one than the number of the second semiconductor layers 25 (i.e., the top layer is the first semiconductor layer).

The first semiconductor layers 20 and second semiconductor layers 25 are provided over substrate 10, and vertically arranged along the Z direction (the normal direction to the principal surface of substrate 10). In some embodiments, substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb, and InP. In certain embodiments, the substrate 10 includes SiₓGe₁₋ₓ, 0≤x≤1. The substrate 10 may include various regions that have been suitably doped with impurities (e.g., p-type or n-type conductivity). The dopants are, for example, boron (BF₂) for an n-type Fin FET and phosphorus for a p-type Fin FET in some embodiments. In certain embodiments, substrate 10 is made of crystalline Si.

The substrate 10 may include in its surface region one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

After the stacked first and second semiconductor layers 20 and 25 are formed, fin structures 29 are formed by using one or more lithography and etching operations, as shown in FIGS. 3A and 3B. The fin structures may be patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

As shown in FIG. 3A, the fin structures 29 extend in the X direction and are arranged in the Y direction. The number of the fin structures is not limited to two as shown in FIG. 3A, and may be as small as one and three or more (as shown in FIG. 3B). In some embodiments, one or more dummy fin structures are formed on both sides of the fin structures to improve pattern fidelity in the patterning operations. As shown in FIG. 3A, the fin structures 29 have upper portions constituted by the stacked first and second semiconductor layers 20, 25, and lower well portions 11 (a mesa structure).

In some embodiments, a width of the upper portion of the fin structure along the Y direction is in a range from about 5 nm to about 80 nm in some embodiments and is in a range from about 10 nm to about 40 nm in other embodiments.

After the fin structures 29 are formed, an insulating material layer including one or more layers of insulating material is formed over the substrate so that the fin structures are fully embedded in the insulating layer. The insulating material for the insulating layer may include silicon oxide, silicon nitride, silicon oxynitride (SiON), SiOCN, SiCN, fluorine-doped silicate glass (FSG), or a low-k dielectric material, formed by LPCVD (low-pressure chemical vapor deposition), plasma-enhanced CVD (PECVD) or flowable CVD. An anneal operation may be performed after the formation of the insulating layer. Then, a planarization operation, such as a chemical mechanical polishing (CMP) method and/or an etch-back method, is performed such that the upper surface of the uppermost second semiconductor layer 25 is exposed from the insulating material layer. In some embodiments, one or more fin liner layers are formed over the fin structures before forming the insulating material layer. In some embodiments, the fin liner layers include a first fin liner layer formed over the substrate 10 and sidewalls of the bottom part of the fin structures 11, and a second fin liner layer formed on the first fin liner layer. The fin liner layers are made of silicon nitride or a silicon nitride-based material (e.g., SiON, SiCN, or SiOCN). The fin liner layers may be deposited through one or more processes such as physical vapor deposition (PVD), chemical vapor deposition (CVD), or atomic layer deposition (ALD), although any acceptable process may be utilized.

Then, as shown in FIG. 3A, the insulating material layer is recessed to form an isolation insulating layer 15 so that the upper portions of the fin structures 29 are exposed. With this operation, the fin structures 29 are separated from each other by the isolation insulating layer 15, which is also called a shallow trench isolation (STI). The isolation insulating layer 15 may be made of suitable dielectric materials, such as silicon oxide, silicon nitride, silicon oxynitride, fluorine-doped silicate glass (FSG); low-k dielectrics, such as carbon doped oxides; extreme low-k dielectrics, such as porous carbon doped silicon dioxide; a polymer, such as polyimide; combinations of these, or the like. In some embodiments, the isolation insulating layer 15 is formed through a process such as CVD, flowable CVD (FCVD), or a spin-on-glass process, although any acceptable process may be used.

In some embodiments, the insulating material layer is recessed until the upper portion of the fin structure (well layer) 11 is exposed. In other embodiments, the upper portion of the fin structure 11 is not exposed. The first semiconductor layers 20 are sacrificial layers that are subsequently partially removed, and the second semiconductor layers 25 are subsequently formed into semiconductor wires or sheets as channel layers of a FET, such as a GAA FET. In other embodiments, the second semiconductor layers 25 are sacrificial layers that are subsequently partially removed, and the first semiconductor layers 20 are subsequently formed into semiconductor wires or sheets as channel layers.

FIG. 3B is an isometric view showing a plurality of fin structures 29 separated by shallow trench isolations 15 after a sacrificial gate dielectric layer 41 is formed over the fin structures 29 and over the shallow trench isolation 15.

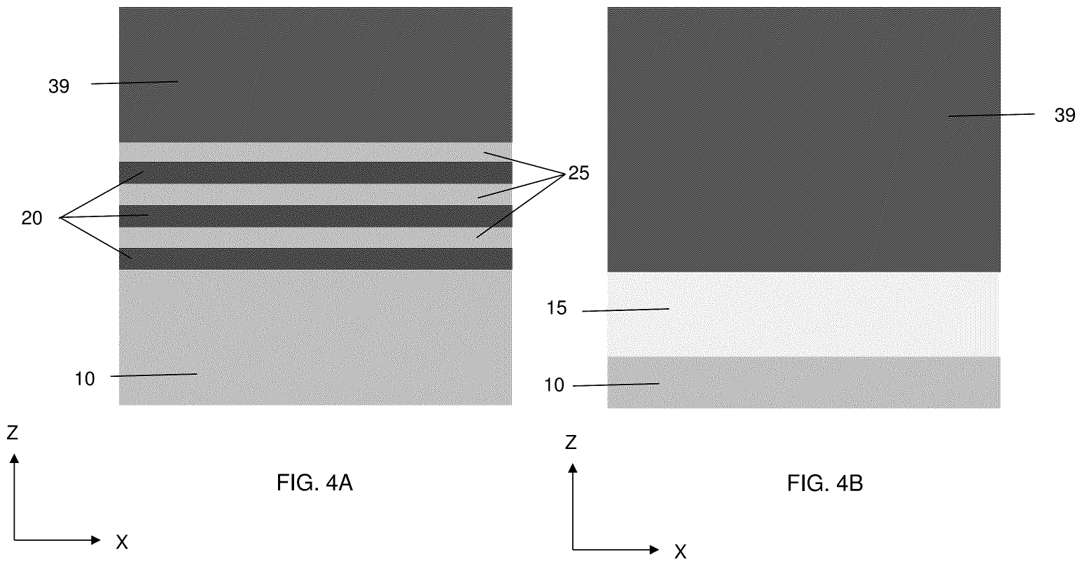

Next, a sacrificial (dummy) gate electrode layer 39 is formed, as shown in FIGS. 4A and 4B. A sacrificial gate electrode layer 39 is formed over the exposed fin structures 29. FIG. 4A is a view cut along line A-A′ (FIG. 1A), and FIG. 4B is a view cut along line B-B′ (FIG. 1A) at an outer gate. The sacrificial gate electrode layer 39 is formed by blanket depositing the sacrificial gate electrode layer 39 over the fin structures 29 such that the fin structures are fully embedded in the sacrificial gate electrode layer 39.

The sacrificial gate electrode layer 39 includes silicon such as polycrystalline silicon or amorphous silicon. The thickness of the sacrificial gate electrode layer 39 is in a range from about 100 nm to about 200 nm in some embodiments. In some embodiments, the sacrificial gate electrode layer 39 is subjected to a planarization operation. The sacrificial gate electrode layer 39 is deposited using CVD, including LPCVD and PECVD, PVD, ALD, or other suitable deposition process. Subsequently, a mask layer (not shown) is formed over the sacrificial gate electrode layer 39.

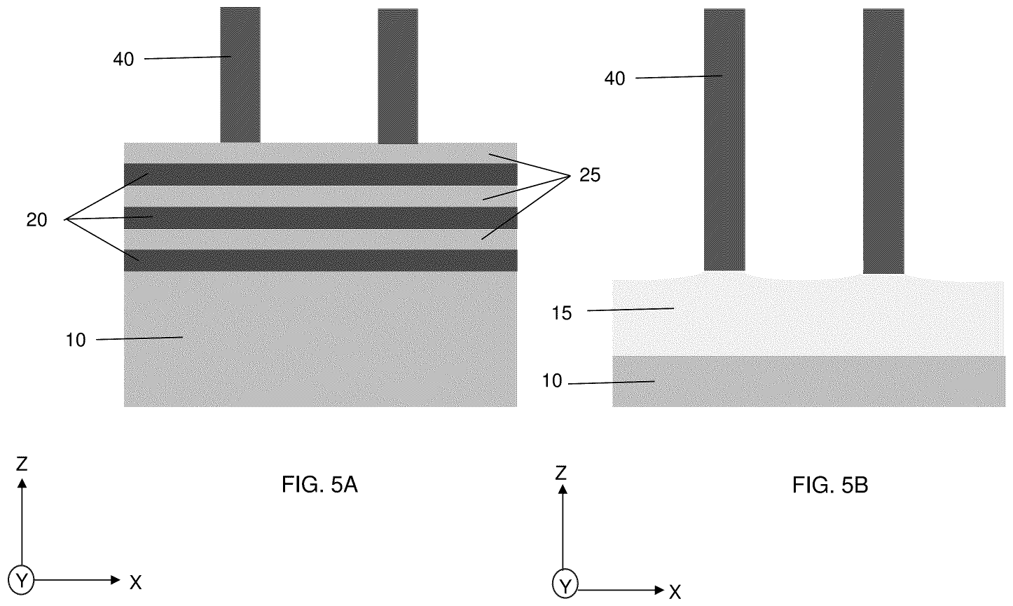

Next, a patterning operation is performed on the mask layer and the sacrificial gate electrode layer 39 is patterned into the sacrificial gate structures 40, as shown in FIGS. 5A and 5B. By patterning the sacrificial gate structures, the stacked layers of the first and second semiconductor layers are partially exposed on opposite sides of the sacrificial gate structures, thereby defining source/drain regions. In some embodiments, one sacrificial gate structure is formed over one or more fin structures, but the number of the sacrificial gate structures per fin structure is not limited to one. Two or more sacrificial gate structures are arranged in the X direction in some embodiments, as shown in FIG. 5A. In certain embodiments, one or more dummy sacrificial gate structures are formed on both sides of the sacrificial gate structures to improve pattern fidelity.

In other embodiments, the sacrificial gate structures 40 are formed by first blanket depositing the sacrificial gate dielectric layer over the fin structures 29. A sacrificial gate electrode layer is then blanket deposited on the sacrificial gate dielectric layer and over the fin structures, such that the fin structures are fully embedded in the sacrificial gate electrode layer. The sacrificial gate electrode layer includes silicon such as polycrystalline silicon or amorphous silicon. The thickness of the sacrificial gate electrode layer is in the range of about 100 nm to about 200 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. Subsequently, a mask layer is formed over the sacrificial gate electrode layer. The mask layer includes a pad silicon nitride layer and a silicon oxide mask layer.

After the sacrificial gate structures 40 are formed, a first cover layer for gate sidewall spacers is formed over the sacrificial gate structures 40. The first cover layer is deposited in a conformal manner so that it is formed to have substantially equal thicknesses on vertical surfaces, such as the sidewalls, horizontal surfaces, and the top of the sacrificial gate structures 40, respectively. In some embodiments, the first cover layer has a thickness in the range from about 5 nm to about 20 nm. The first cover layer includes one or more of silicon nitride, silicon oxide, SiON, SiCN, SiCO, SiOCN, or any other suitable dielectric material. The cover layer can be formed by ALD, CVD, or any other suitable method. In some embodiments, one or more additional cover layers are formed over the first cover layer 45 to form multi-layer gate sidewall spacers.

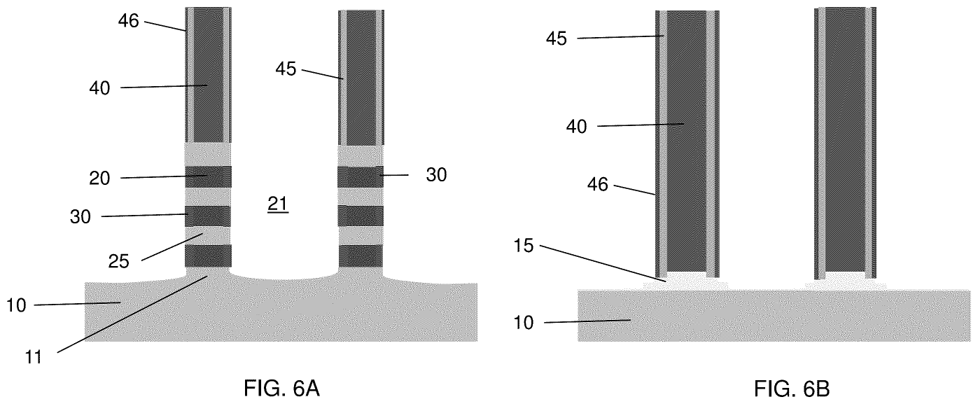

Next, as shown in FIGS. 6A and 6B, the first cover layer is anisotropically etched to remove the first cover layer disposed on the source/drain region while leaving the first cover layer as sidewall spacers 45 on the side faces of the sacrificial gate structure 40. FIG. 6A shows a cross sectional view along line A-A′ (FIG. 1A). Then the stacked structure of the first semiconductor layers 20 and the second semiconductor layer 25 is etched down at the source/drain region, by using one or more lithography and etching operations, thereby forming a source/drain space 21. In some embodiments, the substrate 10 (or the bottom part of the fin structures 11) is also partially etched to form a mesa structure. In some embodiments, an n-type FET and a p-type FET are manufactured separately, and in such a case, a region for one type of FET is processed, and a region for the other type of FET is covered by a protective layer, such as a silicon nitride layer. In some embodiments, the recessed fin structure has a U-shape. In other embodiments, the recessed fin structure has a V-shape showing (111) facets of silicon crystal. In other embodiments, the recess has a reverse trapezoid shape or a rectangular shape.

In some embodiments, the recess is formed by a dry etching process, which may be anisotropic. The anisotropic etching process may be performed using a process gas mixture including BF₂, Cl₂, CH₃F, CH₄, HBr, O₂, Ar, and other etchant gases. Process gases may be activated into a plasma by any suitable method of generating the plasma, such as transformer coupled plasma (TCP) systems, inductively coupled plasma (ICP) systems, and magnetically enhanced reactive ion techniques. The plasma is a remote plasma that is generated in a separate plasma generation chamber connected to the processing chamber in some embodiments. The process gases used in the plasma etching process include etchant gases such as H₂, Ar, other gases, or a combination of gases. In some embodiments, carrier gases, such as N₂, Ar, He, and Xe, are combined with a plasma etching process gas using hydrogen (H) radicals. The H radicals may be formed by flowing H₂ gas into a plasma generation chamber and igniting a plasma within the plasma generation chamber. In some embodiments, an additional gas may be ignited into a plasma within the plasma generation chamber, such as Ar. The H radicals may selectively etch (100) planes over (111) planes or (110) planes. In some cases, the etch rate of the (100) planes is about three times greater than the etch rate of (111) planes. Due to this selectivity, the etching by the H radicals may tend to slow or stop along (111) planes or (110) planes of silicon during the second patterning process.

Further, the first semiconductor layers 20 are laterally etched in the X direction within the source/drain space 21, thereby forming cavities (not shown). When the first semiconductor layers 20 are SiGe and the second semiconductor layers 25 are Si, the first semiconductor layers 20 can be selectively etched by using a wet etchant such as, but not limited to, a mixed solution of H₂O₂, CH₃COOH, and HF, followed by H₂O cleaning. In some embodiments, the etching by the mixed solution and cleaning by water is repeated 10 to 20 times. The etching time by the mixed solution is in the range from about 1 min to about 2 min in some embodiments. The mixed solution is used at a temperature in a range from about 60° C. to about 90° C. in some embodiments. In some embodiments, other etchants are used.

In some embodiments, the cavities have a curved end shape convex toward the first semiconductor layer 20 (lateral U-shape cross section). In other embodiments, the cavity has a lateral V-shape cross section having an apex at the first semiconductor layer 20.

Next, a first insulating layer (not shown) is formed on the etched lateral ends of the first semiconductor layers 20 and on the end faces of the second semiconductor layers 25 in the source/drain space 21 and over the sacrificial gate structure 40. The first insulating layer is conformally formed so that a space is left in the source/drain space 21. The first insulating layer includes one of silicon nitride, silicon oxide, SiON, SiOC, SiCN, and SiOCN, or any other suitable dielectric material. The first insulating layer is made of a different material than the sidewall spacers (first cover layer) 45 in some embodiments and is made of the same material as the sidewall spacers 45 in other embodiments. The first insulating layer can be formed by ALD or any other suitable method. In some embodiments, by forming the first insulating layer, the cavities are fully filled with the first insulating layer.

After the first insulating layer is formed, an etching operation is performed to partially remove the first insulating layer, thereby forming inner spacers 30, as shown in FIGS. 6A and 6B. In some embodiments, after etching of the first insulating layer, insulating portions 46 remain over sidewall spacers 45. In some embodiments, the end face of the inner spacers 30 is recessed more than the end face of the second semiconductor layers 25. The recessed amount is in a range from about 0.2 nm to about 3 nm and is in a range from about 0.5 nm to about 2 nm in other embodiments. In other embodiments, the recessed amount is less than 0.5 nm and may be equal to zero (i.e., the end face of the inner spacer 30 and the end face of the second semiconductor layers 25 are flush with each other). In some embodiments, before forming the first insulating layer, an additional insulating layer having a smaller thickness than the first insulating layer is formed, and thus the inner spacers 30 have a two-layer structure. In some embodiments, the widths (lateral length) of the inner spacers 30 are not constant.

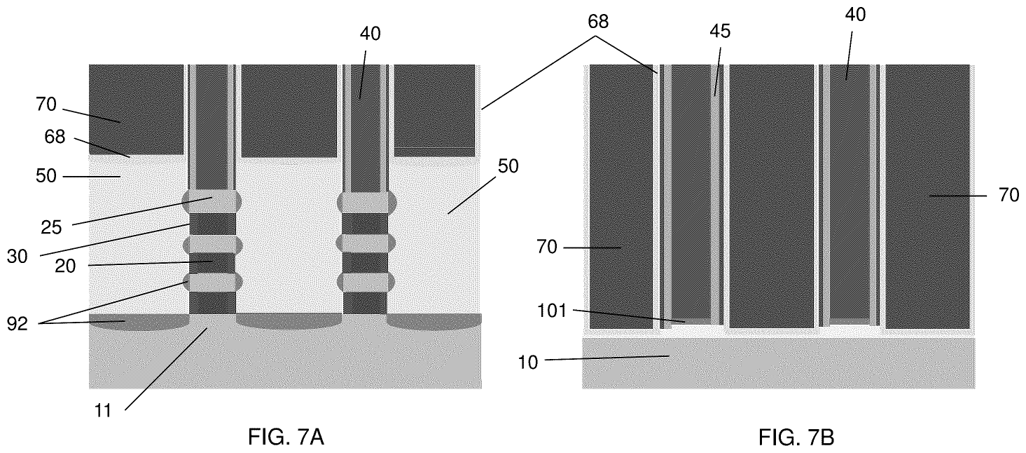

After the inner spacers 30 are formed, an epitaxial layer 92 is formed on the lateral end faces of the second semiconductor layer 25 and the exposed surface of the lower fin structure 11 in some embodiments, as shown in FIG. 7A. In some embodiments, the epitaxial layer 92 includes Si doped with P or As for an n-type FET and doped with B for a p-type FET. In some embodiments, the dopant concentration of the epitaxial layer 92 is higher than the dopant concentration of the second semiconductor layers 25. In some embodiments, the dopant concentration of the epitaxial layer 92 gradually increases from the interface between the first epitaxial layer 92 and the second semiconductor layers 25 or lower fin structure 11 to the source/drain space 21. In some embodiments, the thickness of the epitaxial layer as deposited is in a range from about 1 nm to about 10 nm. In some embodiments, during the epitaxial formation of the epitaxial layer, some of the dopant elements diffuse into the second semiconductor layer 25 or lower fin structure 11 to a depth of about 0.5 nm to about 2 nm.

Next, as shown in FIG. 7A, source/drain structures 50 are formed in the source/drain space 21. In some embodiments, source/drain structures 50 include one or more layers of SiC, SiP, SiAs, and/or SiCP for an n-type FET. In certain embodiments, SiC or SiCP is used. In some embodiments, the source/drain structures 50 include SiGe, SiGeSn, Ge, GeSn, and/or SiSn for a p-type FET. When SiGe is used, the Ge content is about 60 atomic % to about 80 atomic % in some embodiments. In some embodiments, the source/drain structures 50 are formed by an epitaxial process. In some embodiments, the source/drain structures 50 apply tensile stress to the second semiconductor layer 25 for an n-type FET and compressive stress to a p-type FET.

Next, as shown in FIGS. 7A and 7B, an interlayer dielectric (ILD) layer 70 is formed over the source/drain structure 50 and the sacrificial gate structures 40. In some embodiments, an etch stop layer 101 is provided below the sacrificial gate structure 40. In some embodiments, before the ILD layer 70 is formed, a contact etch stop layer (CESL) 68 is formed. Next, the dielectric layer 70 is planarized by chemical mechanical polishing (CMP) to expose the sacrificial gate material of each of the sacrificial gate structures 40, as shown in FIGS. 7A and 7B. The materials for the ILD layer 70 include compounds comprising Si, O, C, and/or H, such as silicon oxide, SiCOH, and SiOC. Organic materials, such as a polymer, including polyimide, may be used for the ILD layer 70. Materials for the CESL 68 include a silicon nitride, a silicon oxide, SiCN, SiON, and SiOCN. The materials for the ILD layer 70 and the etch stop layer 68 are different from each other and thus have different etch selectivities.

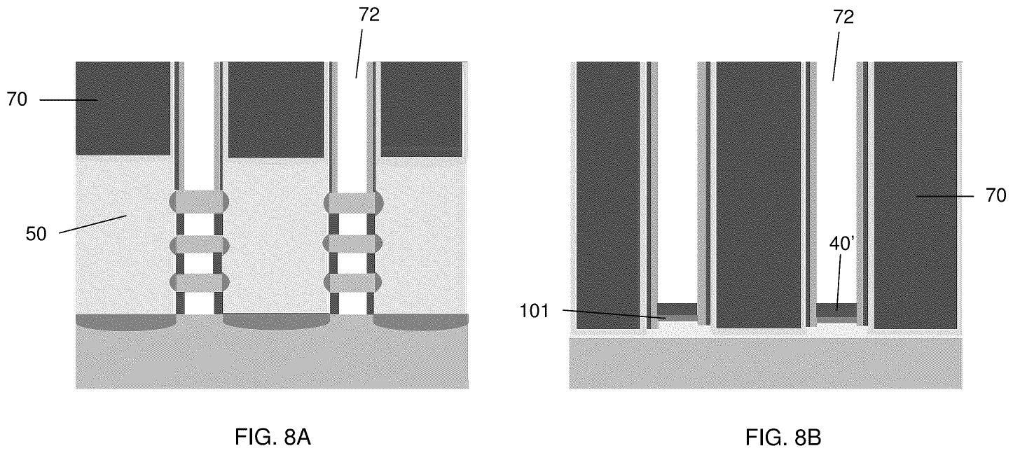

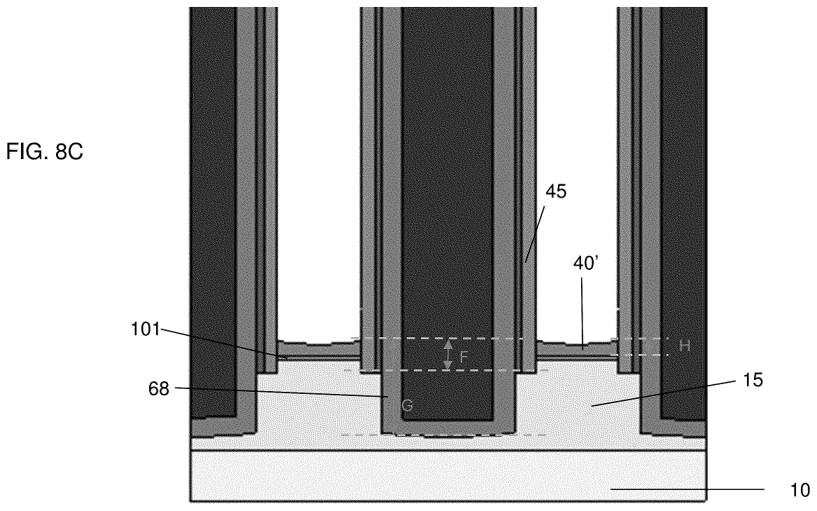

Then, as shown in FIGS. 8A and 8B, the sacrificial gate electrode material of each of the sacrificial gate structures 40 is substantially removed to form gate space 72. The ILD layer 70 protects the source/drain structures 50 during the removal of the sacrificial gate structures 40. In certain embodiments, when the sacrificial gate structures 40 are formed of polysilicon, plasma dry etching is performed to generate the gate space 72. In certain embodiments, a dry silicon or dry by-product etching is performed to substantially remove the sacrificial gate structure. A residual amount 40′ of the sacrificial gate structure remains at the bottom of gate space 72, as shown in FIG. 8B. In certain embodiments, the sacrificial gate dielectric layer 41 is removed by an inside etch removal process.

Etching gases used for removing the sacrificial gate structures 40 include Cl₂, HBr, CH₂F₂, CHF₃, CF₄, CHCIF₂, HF, and NH₃. A passivation gas for selective etching includes N₂, O₂, CO₂, CH₄, and SO₂. A dilute gas for the dry etching includes He, Ar, and N₂. Other conditions for the dry etching process include a power range from 10 W to 4000 W, a pressure range from 1 mTorr to 800 mTorr, and a gas flow rate of 20 sccm to 3000 sccm.

In certain embodiments, the residual amount 40′ of sacrificial gate structure remaining at the bottom of the gate space has a gate thickness H of about 3 to 6 nanometers, as shown in FIG. 8C. With the residual amount 40′ of the sacrificial gate structure, over-etching into the STI 15 and loss of the STI 15 is minimized. In certain embodiments, the height F, measured from an upper surface of the residual amount 40′ of an inner gate to a bottom surface of sidewall spacers 45, ranges from about 7 to 10 nanometers. In other embodiments, the height G, measured from an upper surface of the residual amount 40′ of an inner gate to a bottom surface of the CESL 68, ranges from about 16 to 20 nanometers. In contrast, with conventional sacrificial gate removal techniques, a height, measured from a bottom surface of the over-etched STI of an inner gate to the bottom surface of the sidewall spacers is 10 to 14 nanometers. Further, as a result of the STI loss with conventional techniques, a height, measured from the bottom surface of the over-etched STI of an inner gate to the bottom surface of the CESL is only 4 to 6 nanometers.

In certain embodiments, a ratio of gate thickness H to height F is about 0.3 to 0.9. In certain embodiments, a ratio of gate thickness H to height G is about 0.2 to 0.4. In other embodiments, a ratio of height F to height G is about 0.4 to 0.6. In certain embodiments, the ratios improve a metal gate rounding performance and reduces excessive notching into the STI.

In certain embodiments, after the sacrificial gate structures are removed, the first semiconductor layers 20 are removed, thereby forming nanowires or nanosheets (channel regions) of the second semiconductor layers 25. In certain embodiments, the channel regions are single channel, and in other embodiments multi-channel. The first semiconductor layers 20 can be removed or etched using an etchant that selectively etches the first semiconductor layers 20 against the second semiconductor layers 25. In certain embodiments, the channel region is formed by the removal of adjacent SiGe layers by way of sheet formation. Since the inner spacers 30 were previously formed, the etching of the first semiconductor layers 20 stops at the inner spacers 30. In other words, the inner spacers 30 function as an etch-stop layer for etching of the first semiconductor layers 20.

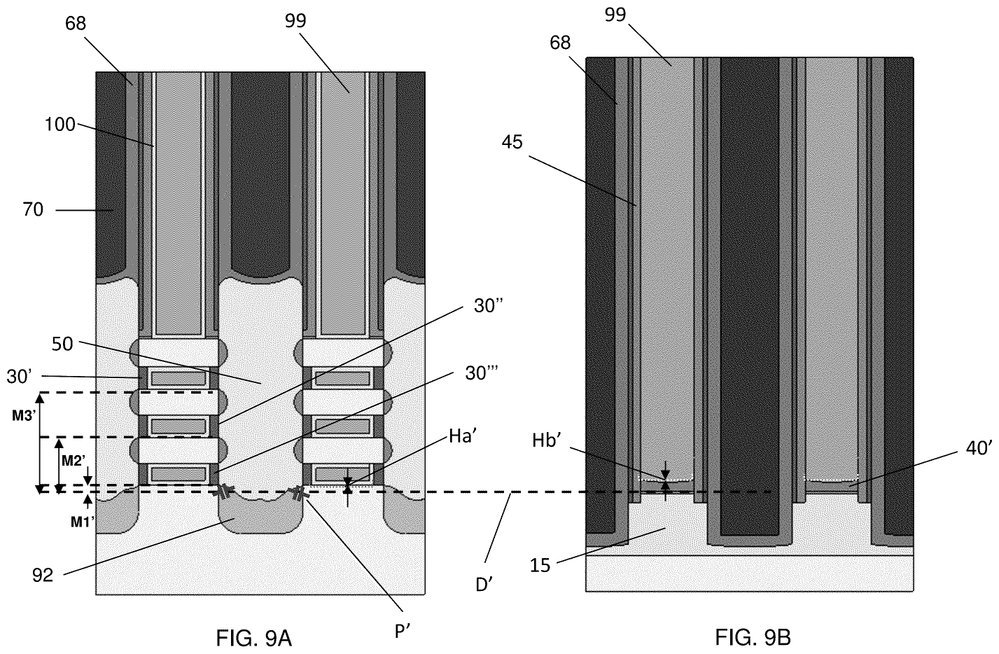

After the semiconductor nanowires or nanosheets (channel regions) of the second semiconductor layers 25 are formed, metal gate structures 99 are formed as shown in FIGS. 9A and 9B. In certain embodiments, a high-k gate dielectric layer 100 is formed before the metal gate electrode is formed. In some embodiments, the high-k dielectric layer is made of hafnium oxide, zirconium oxide, aluminum oxide, aluminum nitride, titanium nitride, silicon nitride, silicon oxynitride, silicon oxy-carbo-nitride, or tantalum nitride. In some embodiments, the structure and/or material of the gate electrode for the n-type GAA FET is different from the structure and/or material of the gate electrode for the p-type GAA FET.

In some embodiments, the metal gate structures 99 includes one or more work function adjustment layers (not shown). In certain embodiments, the work function adjustment layers are made of a conductive material such as a single layer of TiN, TaN, TaAlC, TiC, TaC, Co, Al, TiAl, HfTi, TiSi, TaSi or TiAlC, or a multilayer of two or more of these materials. In some embodiments, one or more of TiAlC, Al, TiAl, TaN, TaAlC, TiN, TiC, and Co are used as the work function adjustment layer for the p-channel FET. For an n-channel FET, one or more of TaN, TaAlC, TiN, TIC, Co, TiAl, HfTi, TiSi, and TaSi are used as the work function adjustment layer. The work function adjustment layer may be formed by ALD, PVD, CVD, e-beam evaporation, or other suitable process. Further, the work function adjustment layer may be formed separately for the n-channel FET and the p-channel FET which may use different metal layers.

The gate electrode layer is formed on the work function adjustment layer to surround each channel layer. The gate electrode layer includes one or more layers of conductive material, such as tungsten, cobalt, copper, aluminum, titanium, tantalum, molybdenum, tantalum nitride, nickel silicide, cobalt silicide, TiN, WN, TiAl, TiAlN, TaCN, TaC, TaSiN, metal alloys, other suitable materials, and/or combinations thereof.

The gate electrode layer may be formed by CVD, ALD, electro-plating, or other suitable method. In certain embodiments, the gate electrode layer is also deposited over the upper surface of the ILD layer 70. The gate dielectric layer (including high-k dielectrics), a work function adjustment layer, and the gate electrode layer formed over the ILD layer 70 are then planarized by using, for example, CMP, until the top surface of the ILD layer 70 is revealed. In some embodiments, after the planarization operation, the gate electrode layer is recessed and a cap insulating layer (not shown) is formed over the recessed gate electrode. In certain embodiments, the cap insulating layer includes one or more layers of a silicon nitride-based material, such as silicon nitride. In other embodiments, the cap insulating layer is formed by depositing an insulating material followed by a planarization operation.

After metal gate replacement is performed in accordance with the embodiments described herein, less extension of the metal gate near to epitaxial source/drain region is evident, as shown in FIGS. 9A and 9B. In certain embodiments, a difference in metal depth Ha′ (FIG. 9A) to metal depth Hb′ (FIG. 9B) is about 1 to 3 nanometers which is an improvement over conventional techniques which resulted in differences in the metal depth of about 14 to 18 nanometers due to the extension of the metal gate into the STI region. Moreover, in certain embodiments, a distance P′ (FIG. 9A) of about 10 to 15 nanometers is provided between the epitaxial region 92 to the bottom of the metal gate, which is an improvement over conventional techniques that produce a distance of only about 3 to 8 nanometers from an epitaxial region to a bottom of the metal gate.

Further, in certain embodiments, a depth M1′ (FIG. 9A) from the bottom of the inner spacer 30″′ to a bottom D′ of metal gate structure 99 inclusive of the residual sacrificial gate portion 40′, is about 4 to 6 nanometers, whereas with conventional techniques, a depth of more than about 16 to 20 nanometers results due to the extension of the metal gate into the STI region. In other embodiments, a depth M2′ from the bottom of the inner spacer 30″ to a bottom D′ of metal gate structure 99 inclusive of the residual sacrificial gate portion 40′, is about 19 to 21 nanometers, whereas with conventional techniques, a depth of more than about 31 to 35 nanometers results due to the extension of the metal gate into the STI region. In yet other embodiments, a depth M3′ from the bottom of the inner spacer 30′ to a bottom D′ of metal gate structure 99 which includes residual sacrificial gate portion 40′ is about 34 to 36 nanometers, whereas with conventional techniques, a depth of more than about 46 to 50 nanometers results due to the extension of the metal gate into the STI region. In certain embodiments, by reducing depths of the M1′, M2′, and M3′, compared to depths produced from conventional techniques, an appropriate distance between the bottom of the metal gate electrode and the epitaxial source/drain region is maintained and thereby reduced parasitic capacitance at the bottom of the metal gate electrode is achieved.

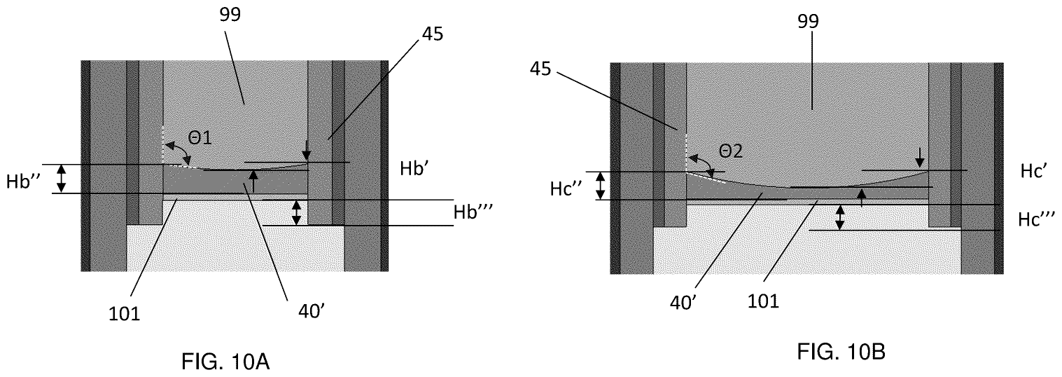

Gate lengths may vary in some semiconductor devices according to the present disclosure. Depending on the application of a specific transistor, the gate length and the underlying channel length are larger in some transistors than other transistors. In some embodiments, a length of a first gate (FIG. 10A) is smaller than a length of a larger second gate (FIG. 10B) in accordance with some embodiments. In certain embodiments, the upper surface of the residual amount 40′ has a curved surface in the first (or small gate) (FIG. 10A) and the second (or large gate) (FIG. 10B). In certain embodiments, an angle Θ1 (FIG. 10A) of the small gate, measured from a first interface of the sidewall spacer 45 and the metal gate electrode 99 to a second interface of the metal gate 99 and the residual amount 40′ of the sacrificial gate structure, is from about 92 to 95 degrees. In certain embodiments, an angle Θ2 (FIG. 10B) of the large gate, measured from a first interface of the sidewall spacer 45 and the metal gate 99 to a second interface of the metal gate 99 and the residual amount 40′ of the sacrificial gate structure, is from about 100 to 105 degrees.

Moreover, in certain embodiments, for the small gate (FIG. 10A), a height Hb′ of about 1 to 3 nanometers exists between an upper surface of the residual amount 40′ of the sacrificial gate structure at its thickest portion to an upper surface of the residual amount 40′ of the sacrificial gate structure at its thinnest portion. In certain embodiments, for the large gate (FIG. 10B), a height Hc′ of about 3 to 5 nanometers exists between an upper surface of the residual amount 40′ of the sacrificial gate structure at its thickest portion to an upper surface of the residual amount 40′ of the sacrificial gate structure at its thinnest portion.

In other embodiments, for the small gate (FIG. 10A), a height Hb″ of about 3 to 6 nanometers exists between an upper surface of the residual amount 40′ of the sacrificial gate structure at its thickest portion to a bottom surface of the residual amount 40′ of the sacrificial gate structure. In other embodiments, for the large gate (FIG. 10B), a height Hc″ of about 1 to 4 nanometers exists between an upper surface of the residual amount 40′ of the sacrificial gate structure at its thickest portion to a bottom surface of the residual amount 40′ of the sacrificial gate structure.

In yet other embodiments, for the small gate (FIG. 10A), a height Hb′″ of about 4 to 8 nanometers exists between the bottom surface of the sidewall spacers 45 to a bottom surface of the etch stop layer 101. In other embodiments, for the large gate (FIG. 10B), a height Hc′″ of about 4 to 8 nanometers exists between the bottom surface of the sidewall spacers 45 to the bottom surface of the etch stop layer 101. In certain embodiments, the overall height of the gate structure 99 is about 100 to 200 nanometers. In some embodiments, a ratio of a height of the residual amount 40′ to the overall height of the gate structure 99 is about 0.02 to 0.06, which improves a metal gate rounding performance and reduces excessive notching into the STI.

In certain embodiments, after completion of the GAA FET device (FIG. 1D), the parasitic capacitance of the device is reduced since excessive extension of the metal gate into the STI region 15 and loss of STI region 15 are minimized. Since the metal gate fill is precluded from extending near the source/drain epitaxial region the parasitic capacitance is reduced and the electrical current and yield of the device are improved.

It will be understood that not all advantages have been necessarily discussed herein, no particular advantage is required for all embodiments or examples, and other embodiments or examples may offer different advantages.

According to an embodiment of the disclosure, a method of fabricating a semiconductor device includes forming an isolation insulating layer over a substrate. A sacrificial gate layer is formed over the isolation insulating layer. The sacrificial gate layer is patterned to form sacrificial gate structures. A spacer layer is formed over the sacrificial gate structures. An interlayer dielectric layer is formed over the sacrificial gate structures. The sacrificial gate structures are removed to form openings over the isolation insulating layer. A residual amount of each sacrificial gate structure remains at the bottom of a respective opening over the isolation insulating layer. Metal gate electrodes are formed in the openings. The metal gate electrodes comprise a first material and the residual amount comprises a second material different from the first material. In an embodiment, the isolation insulating layer comprises silicon oxide, silicon nitride, silicon oxynitride, fluorine-doped silicate glass (FSG); carbon-doped oxide; porous carbon-doped silicon dioxide, or a polymer. In an embodiment, source/drain regions are formed over the substrate on opposing sides of the plurality of sacrificial gate structures. In an embodiment, the residual amount of sacrificial gate structure includes polycrystalline silicon or amorphous silicon. In an embodiment, the interlayer dielectric layer comprises silicon oxide or polyimide. In an embodiment, the metal gate electrodes include one or more layers of aluminum, copper, titanium, tantalum, tungsten, cobalt, molybdenum, hafnium oxide, tantalum nitride, nickel silicide, cobalt silicide, TiN, WN, TiAl, TiAlN, TaCN, TaC, or TaSiN. In an embodiment, fin structures are formed that protrude from the substrate. In other embodiments, nanostructures are formed over each fin structure. In an embodiment, a ratio of a height of the residual amount to a height of the metal gate electrodes is about 0.02 to 0.06. In an embodiment, sidewall spacers, formed from the spacer layer, are formed on sides of the metal gate electrodes. A ratio of a height of the residual amount to a height measured from an upper surface of the residual amount to a bottom surface of the sidewall spacers is 0.3 to 0.9.

According to another embodiment of the disclosure, a method of fabricating a semiconductor device includes disposing an insulating isolation layer over a substrate. A sacrificial gate layer is disposed over the insulating isolation layer. The sacrificial gate layer is etched to form sacrificial gate structures. A spacer layer is disposed over the sacrificial gate structures. An interlayer dielectric layer is disposed over the sacrificial gate structures. The sacrificial gate structures are etched to form openings over the insulating isolation layer. Conductive gate material is disposed over remaining portions of the sacrificial gate structures present in respective bottoms of the plurality of openings. The remaining portions of the sacrificial gate structures are disposed between the conductive gate material and the insulating isolation layer, and the conductive gate material is different from a material of sacrificial gate layer. In an embodiment, sidewall spacers, formed from the spacer layer, are formed on the sides of the conductive gate material, wherein a ratio of a height of one of the remaining portions to a height measured from an upper surface of the one remaining portion to a bottom surface of the sidewall spacers is 0.3 to 0.9. In an embodiment, the remaining portions of the sacrificial gate structures include polycrystalline silicon or amorphous silicon. In an embodiment, the etching of the sacrificial gate structures includes plasma etching. In an embodiment, the remaining portions of the sacrificial gate structures include curved upper surfaces. In an embodiment, fin structures are disposed that protrude from the substrate; and nanostructures are disposed over each fin structure.

According to another embodiment of the disclosure, a semiconductor device includes a substrate. An insulating isolation region is disposed over the substrate. Gate structures are disposed over the insulating isolation region. Each gate structure includes a first layer having a first height made of a first conductive material disposed over the insulating isolation region and a second layer having a second height made of a second conductive material different from the first conductive material disposed over the first layer. A ratio of the first height to the second height ranges from 0.02 to 0.06. An interlayer dielectric layer disposed between the gate structures. In an embodiment, source/drain regions are disposed over the substrate on opposing sides of the gate structures. In an embodiment, the first conductive material includes one or more layers of aluminum, copper, titanium, tantalum, tungsten, cobalt, molybdenum, hafnium oxide, tantalum nitride, nickel silicide, cobalt silicide, TiN, WN, TiAl, TiAlN, TaCN, TaC, or TaSiN. In an embodiment, the second conductive material includes polycrystalline silicon or amorphous silicon.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of fabricating a semiconductor device comprising:
forming an isolation insulating layer over a substrate;
forming a sacrificial gate layer over the isolation insulating layer;
patterning the sacrificial gate layer to form a plurality of sacrificial gate structures;
forming a spacer layer over the plurality of sacrificial gate structures;
forming an interlayer dielectric layer over the plurality of sacrificial gate structures;
removing the plurality of sacrificial gate structures to form a plurality of openings over the isolation insulating layer, wherein a residual amount of each sacrificial gate structure remains at a bottom of a respective opening over the isolation insulating layer; and
forming metal gate electrodes in the plurality of openings,
wherein the metal gate electrodes comprise a first material and the residual amount comprises a second material different from the first material.

2. The method of claim 1, wherein the isolation insulating layer comprises silicon oxide, silicon nitride, silicon oxynitride, fluorine-doped silicate glass (FSG); carbon doped oxide; porous carbon doped silicon dioxide, or a polymer.

3. The method of claim 1, further comprising forming source/drain regions over the substrate on opposing sides of the plurality of sacrificial gate structures.

4. The method of claim 1, wherein the residual amount of sacrificial gate structure comprises polycrystalline silicon or amorphous silicon.

5. The method of claim 1, wherein the interlayer dielectric layer comprises silicon oxide or polyimide.

6. The method of claim 1, wherein the metal gate electrodes comprise one or more layers of aluminum, copper, titanium, tantalum, tungsten, cobalt, molybdenum, hafnium oxide, tantalum nitride, nickel silicide, cobalt silicide, TiN, WN, TiAl, TiAlN, TaCN, TaC, or TaSiN.

7. The method of claim 1, further comprising forming fin structures protruding from the substrate.

8. The method of claim 7, further comprising forming nanostructures over each fin structure.

9. The method of claim 1, wherein a ratio of a height of the residual amount to a height of the metal gate electrodes is 0.02 to 0.06.

10. The method of claim 1, further comprising:
sidewall spacers, formed from the spacer layer, are formed on sides of the metal gate electrodes, wherein
a ratio of a height of the residual amount to a height measured from an upper surface of the residual amount to a bottom surface of the sidewall spacers is 0.3 to 0.9.

11. A method of fabricating a semiconductor device comprising:
disposing an insulating isolation layer over a substrate;
disposing a sacrificial gate layer over the insulating isolation layer;
etching the sacrificial gate layer to form a plurality of sacrificial gate structures;
disposing a spacer layer over the plurality of sacrificial gate structures;
disposing an interlayer dielectric layer over the plurality of sacrificial gate structures;
etching the plurality of sacrificial gate structures to form a plurality of openings over the insulating isolation layer; and
disposing conductive gate material over remaining portions of the plurality of sacrificial gate structures present in respective bottoms of the plurality of openings,
wherein the remaining portions of the plurality of sacrificial gate structures are disposed between the conductive gate material and the insulating isolation layer, and
the conductive gate material is different from a material of the sacrificial gate layer.

12. The method of claim 11, further comprising:
sidewall spacers, formed from the spacer layer, are formed on sides of the conductive gate material, wherein
a ratio of a height of one of the remaining portions to a height measured from an upper surface of the one remaining portion to a bottom surface of the sidewall spacers is 0.3 to 0.9.

13. The method of claim 11, wherein the remaining portions of the plurality of sacrificial gate structures comprise polycrystalline silicon or amorphous silicon.

14. The method of claim 11, wherein a ratio of a height of one of the remaining portions to a height of the conductive gate material is 0.02 to 0.06.

15. The method of claim 11, wherein the remaining portions of the plurality of sacrificial gate structures include curved upper surfaces.

16. The method of claim 11, further comprising:
disposing fin structures protruding from the substrate; and
disposing nanostructures over each fin structure.

17. A semiconductor device comprising:
a substrate;
an insulating isolation region disposed over the substrate;
a plurality of gate structures disposed over the insulating isolation region, wherein each gate structure comprises a first layer having a first height made of a first conductive material disposed over the insulating isolation region and a second layer having a second height made of a second conductive material different from the first conductive material disposed over the first layer,
wherein a ratio of the first height to the second height ranges from 0.02 to 0.06; and
an interlayer dielectric layer disposed between the plurality of gate structures.

18. The semiconductor device of claim 17, further comprising:
source/drain regions disposed over the substrate on opposing sides of the plurality of gate structures.

19. The semiconductor device of claim 17, wherein the second conductive material comprises one or more layers of aluminum, copper, titanium, tantalum, tungsten, cobalt, molybdenum, hafnium oxide, tantalum nitride, nickel silicide, cobalt silicide, TiN, WN, TiAl, TiAlN, TaCN, TaC, or TaSiN.

20. The semiconductor device of claim 17, wherein the first conductive material comprises polycrystalline silicon or amorphous silicon.
